(19) United States
(12) Patent Application Publication
(10) Pub. No.: US 2018/0151468 A1
(43) Pub. Date: May 31, 2018

(54) DEVICE INTEGRATION OF ACTIVE COOLING SYSTEMS

(71) Applicant: NANOAIR LTD., Yogneam Illit (IL)

(72) Inventors: Ekaterina AXELROD, Jerusalem (IL); Eran FINE, Tel-Aviv (IL); Shlomo OREN, RaAnana (IL); Ziv HERMON, Modiln (IL)

(21) Appl. No.: 15/575,365

(22) PCT Filed: May 17, 2016
(86) PCT No.: PCT/IB2016/000904

§ 371 Date: Nov. 19, 2017

Related U.S. Application Data
(60) Provisional application No. 62/163,395, filed on May 19, 2015.

(51) Int. Cl. H01L 23/367; B81B 7/00; H01L 23/467

(52) U.S. Cl. CPC H01L 23/3675; H01L 23/467; B81B 7/0093

(57) ABSTRACT

In various embodiments, component-level and product-level devices incorporated one or more low-profile cooling devices for dissipating heat. The low-profile cooling devices may include multiple benders arranged on a substrate. The benders are actuated so as to cause movement thereof, thereby producing an air flow.

### CROSS-REFERENCE TO RELATED APPLICATION

This application claims priority to and the benefit of, and incorporates herein by reference in its entirety, U.S. Provisional Patent Application No. 62/163,395, which was filed on May 19, 2015.

### FIELD OF THE INVENTION

In various embodiments, the present invention relates generally to active cooling systems and methods for integrating the active cooling systems into various devices.

### BACKGROUND

As semiconductor manufacturing technology has evolved to permit ever-greater microprocessor core frequencies and power consumption, heat extraction has emerged as a key factor limiting continued progress. If waste heat cannot be removed from a microprocessor continuously, reliably and without excessive power consumption that would itself contribute to the heat load, the device cannot be used; it would quickly succumb to the heat it generates. Heat removal is even more challenging in mobile environments, which tend to involve thin, light form factors. Indeed, mobile platforms often operate at reduced frequencies precisely to reduce power and limit heat generation. That poses a challenge for manufacturers, as consumers demand more from their mobile devices—sleeker form factors, faster connectivity, richer and bigger displays, and better multimedia capabilities.

Beyond the basic mechanical and thermodynamic challenges of heat removal, as well as consumer acceptability in terms of factors such as noise, any heat-removal technology must be readily integrated with the devices it will cool, in terms of both mechanics and manufacturability. Heat-removal technologies that cannot be made mechanically compatible with a device, or that cannot be integrated cost-effectively within the final product containing the device and without interfering with the product's form factor, will not be adopted.

### SUMMARY

Embodiments of the present invention utilize various strategies for integrating low-profile cooling systems at the component level (e.g., with a microprocessor or battery) or at the product level (e.g., within a smart phone or tablet). In many implementations, the cooling system is fabricated from micro-electromechanical system (MEMS) technology and electroactive polymers (EAPs) and includes flexible fins or benders that can be repeatedly actuated to create an air flow for dissipating heat. In various embodiments, and as further described in U.S. Ser. No. 14/936,107 (filed on Nov. 9, 2015) and Ser. No. 15/092,009 (filed on Apr. 6, 2016), the entire disclosures of which are hereby incorporated by reference, each bender component may include a fan member, an anchor affixed to a substrate, and a flexible beam connecting the fan member to the anchor. An EAP actuator overlies the beam. In these embodiments, application of an electric field to the EAP actuator causes it to contract, tugging the normally flat beam so that it bends, and consequently causing the fan member to move. The electric fields applied to the various EAP actuators may have the same or different amplitudes, frequencies, and/or phases such that the fan members vibrate with the same or different amplitude, frequencies, and/or phases in a simultaneous, sequential, or any desired manner to collectively produce a desired air flow parameter (e.g., a flow rate or a flow direction). For example, the benders may be actuated at the same amplitude and frequency but at different phases such that the movements thereof collectively form a “wave” travelling along a predetermined direction. Alternatively, a selected subset of the benders may be actuated simultaneously at the same amplitude to achieve a predetermined flow rate and/or flow direction.

It should be understood, however, that the approaches described herein are also applicable to many cooling devices providing convectional heat flow away from the surface to be cooled. Such devices may convect air or other gas (e.g., nitrogen or an inert gas) or a liquid such as water (which may contain additives, such as a glycol), and may be based on any material that exhibits a mechanical change (expansion, contraction, rotation, deformation, etc.) due to an external stimulus (voltage, current, magnetic field, pressure, temperature, etc.), for example, piezoelectric actuators, shape memory polymers, shape memory alloys, magnetorestrictive materials, and dielectric elastomers.

Component-level devices that can be cooled include any type of integrated circuit (microprocessor, application-specific integrated circuit (ASIC), RF chip, memory chip, etc.) and batteries; product-level devices that can be cooled include smart phones, tablets, laptops, hard disk drives, circuit boards (e.g., graphics cards), displays, and peripheral components.

Accordingly, in one aspect, the invention relates to a cooling device comprising, in various embodiments, a surface for collecting heat; a heat-exchange manifold comprising a plurality of vanes; a heat pipe having a first end in thermal contact with the heat-collecting surface and a second end in contact with the heat-exchange manifold; and in contact with the heat pipe and/or the heat-exchange manifold, a cooling unit comprising a plurality of benders each comprising (i) a fan member, (ii) a beam, and (iii) at least one electroactive actuator associated with the beam for transmitting force thereto, the electroactive actuators being responsive to a time-varying electrical signal whereby the fan members vibrate at a frequency corresponding to the signal and collectively produce an air flow. The benders may be integral with or attached to the heat pipe. In some embodiments, the heat-exchange manifold comprises a plurality of vanes, and the benders are integral with or attached to one side or both sides of a plurality of the vanes. The benders may be arranged on a thermally conductive retention member, which may itself be in contact with the heat pipe and/or the heat-exchange manifold. The retention member may be spaced from the heat pipe and/or the heat-exchange manifold by a plurality of thermally conductive spacers.

In some embodiments, the benders all have a common orientation so that the flows produced by the benders are substantially additive. In other embodiments, at least some of the benders have different orientations. The electroactive actuator may be mechanically coupled to the beam. The beam may be made of an electroactive polymer.

In another aspect, the invention pertains to a self-cooling integrated circuit comprising, in various embodiments, an integrated circuit die; a device substrate having a first surface to which a first surface of the die is attached, the device substrate including a plurality of contacts on a second surface thereof opposed to the first surface, at least some of the contacts facilitating electrical connection to the die; over a second surface of the die opposed to the first surface, a cooling unit comprising a plurality of benders each comprising (i) a fan member, (ii) a beam, and (iii) at least one electroactive actuator associated with the beam for transmitting force thereto, the electroactive actuators being responsive to a time-varying electrical signal whereby the fan members vibrate at a frequency corresponding to the signal and collectively produce an air flow.

In some embodiments, the benders are suspended by a retention member above the second surface of the die, whereas in other embodiments, the benders rise from a retention member in contact with the second surface of the die. The cooling unit may be electrically connected to the die and may receive the time-varying electrical signal from the die. For example, the cooling unit may be electrically connected to the contacts and may receive power via the contacts. In various embodiments, the cooling unit is spaced from the die by a plurality of thermally conductive spacers. The die may have a cavity and the cooling unit may reside within the cavity.

The benders may be arranged on a thermally conductive retention member or may be arranged on and integral with the second surface of the die. All benders may have a common orientation so that the flows produced by the benders are substantially additive, or various of the benders may have different orientations. The electroactive actuator may be mechanically coupled to the beam, which may itself be made of an electroactive polymer.

In some embodiments, the integrated circuit has a metal lid overlying the die. The lid may comprise an opening where coextensive with the cooling unit therebeneath, and the opening may be bounded by a peripheral seal against the die. The lid may comprise a plurality of peripheral openings and be continuous and unperforated where coextensive with the cooling unit therebeneath.

In still another aspect, the invention pertains to a method of manufacturing a self-cooling device. In various embodiments, the method comprises fabricating an integrated circuit die; and fabricating, on the die, a plurality of benders, each comprising (i) a fan member, (ii) a beam, and (iii) at least one electroactive polymer associated with the beam for transmitting force thereto. Fabricating the benders may involve providing electrical connections between the benders and the die. The benders may be formed utilizing micro-electromechanical system (MEMS) technology. For example, formation of the benders may comprise forming a substrate over the die; forming a first electrode layer on the substrate; depositing an electroactive polymer on the first electrode layer; forming a second electrode layer; releasing a portion of the substrate from the first electrode layer; releasing the electroactive polymer; and separating the plurality of the benders.

As used herein, the terms “approximately,” “roughly,” and “substantially” mean ±10%, and in some embodiments, ±5%. Reference throughout this specification to “one example,” “an example,” “one embodiment,” or “an embodiment” means that a particular feature, structure, or characteristic described in connection with the example is included in at least one example of the present technology. Thus, the occurrences of the phrases “in one example,” “in an example,” “one embodiment,” or “an embodiment” in various places throughout this specification are not necessarily all referring to the same example. Furthermore, the particular features, structures, routines, steps, or characteristics may be combined in any suitable manner in one or more examples of the technology. The headings provided herein are for convenience only and are not intended to limit or interpret the scope or meaning of the claimed technology.

### BRIEF DESCRIPTION OF THE DRAWINGS

In the drawings, like reference characters generally refer to the same parts throughout the different views. Also, the drawings are not necessarily to scale, with an emphasis instead generally being placed upon illustrating the principles of the invention. In the following description, various embodiments of the present invention are described with reference to the following drawings, in which:

FIGS. 1A through 4D schematically illustrate exemplary convective cooling systems amenable to integration in accordance with various embodiments of the present invention.

FIG. 4E is a schematic sectional side view of movement of an exemplary cooling system as shown in FIG. 4D.

FIG. 5 is a perspective view of a conventional fan-based cooling solution for CPUs.

FIGS. 6A and 6B are sectional elevations of a fan-based cooling solution that incorporates a low-profile cooling unit in accordance with embodiments of the invention.

FIGS. 6C and 6D are perspective and elevational views, respectively, of a low-profile cooling unit integrated with cooling fins or vanes.

FIGS. 7A-7C are plan and elevational views of a low-profile cooling unit disposed above a conventionally packaged integrated circuit die.

FIGS. 7D and 7E are plan and elevational views of a low-profile cooling unit disposed within an accommodating cavity etched into an integrated circuit die.

FIG. 7F is an elevational view of cooling benders disposed around at least a portion of the periphery of an integrated circuit package substrate.

FIGS. 7G and 7H are plan and elevational view of low-profile cooling units disposed in openings within a package substrate or circuit board.

FIG. 8A is a sectional elevation of a conventional lidded integrated circuit device.

FIGS. 8B and 8C are sectional elevations showing integration of low-profile cooling units into the device depicted in FIG. 8A.

FIG. 9A is a sectional elevation of a conventional smart phone or tablet device.

FIGS. 9B-9E are sectional elevations showing integration of low-profile cooling units into the device depicted in FIG. 9A.

FIG. 10A is a sectional elevation of a conventional smart phone or tablet device emphasizing the battery component.

FIG. 10B is a sectional elevation showing integration of low-profile cooling units into the device depicted in FIG. 10A.

FIGS. 11A and 11B are perspective views of alternating arrangements of battery cells and low-profile cooling units in accordance with embodiments of the invention.

### DETAILED DESCRIPTION

### A. Cooling Systems for Heat Dissipation

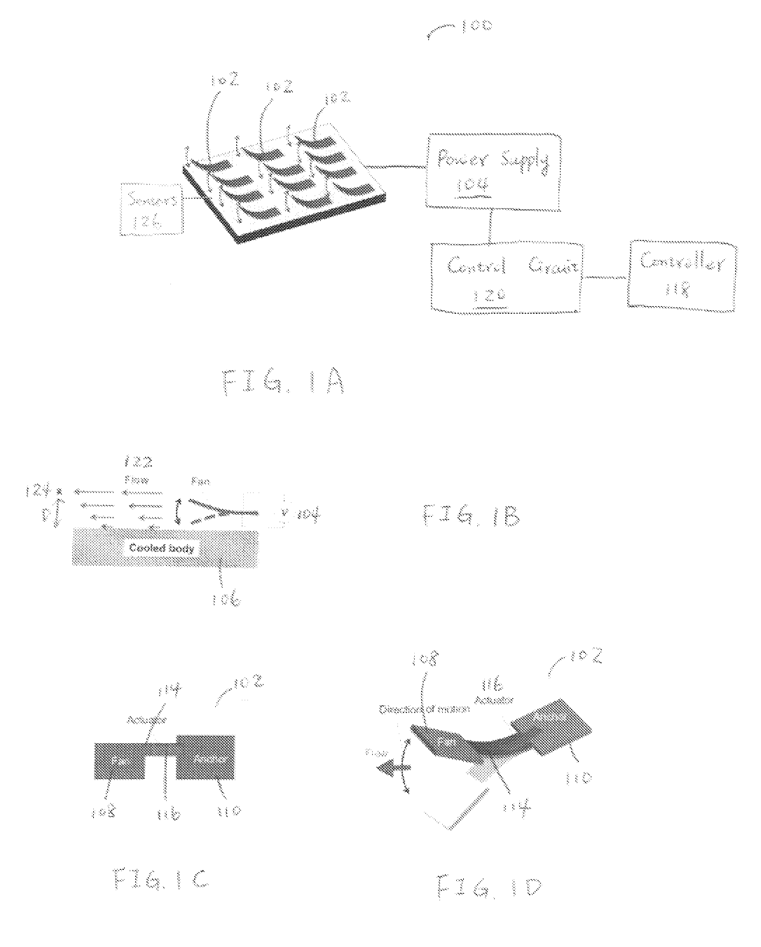

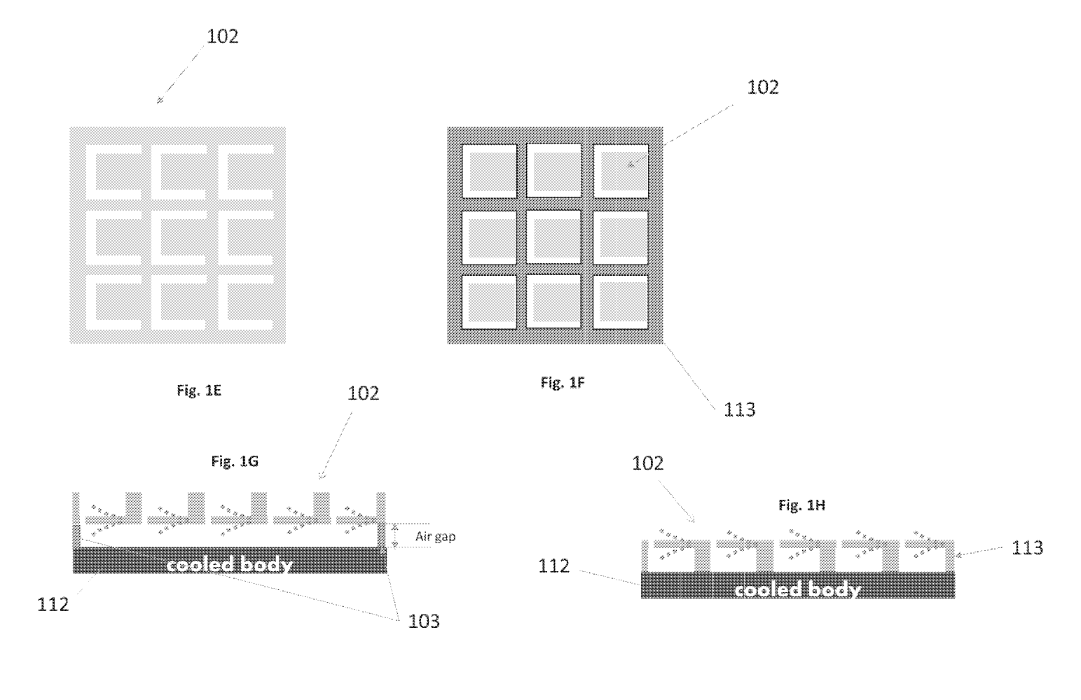

Refer first to FIGS. 1A and 1B, which illustrate a cooling system 100 having a series of flexible benders (or fins) 102 and a power supply 104 for supplying power (i.e., a voltage or a current) to actuate the benders 102. The power supply 104 may be provided by any appropriate power source, such as an AC mains supply, other conventional AC supply, a conventional DC supply, or a combined AC and DC supply. Of particular interest herein, however, are configurations in which the power supply 104 is provided by the cooled system 100, e.g., the battery of a mobile platform, and control of the cooling system 100 is also provided by control hardware and software of the cooled device via data connections thereto.

The benders 102 may be arranged in an array at the surface of a cooled body 106 (i.e., a component generating heat that requires cooling) or at positions close thereto. The array may comprise or consist of a single row, a single column or a matrix of the benders 102. In some embodiments, each of the benders 102 in the array has a common orientation such that the air flows produced by each of the benders 102 are substantially additive. In alternative embodiments, the benders 102 may be arranged in a pattern or without coordination, i.e., they need not be spaced regularly or arranged in a regular pattern. The array of benders 102 may be disposed on a planar surface, as illustrated, or a curved or otherwise shaped surface that can be accommodated by the space close to the cooled body 106 in an electronic device (e.g., a computer, a smart phone, a tablet, a lighting system, a battery, etc.). The dimensions of the bender array may vary, depending on the application, between a few hundred micrometers to a few millimeters.

Referring to FIGS. 1C and 1D, in various embodiments, each bender 102 includes a fan member 108, an anchor 110 affixed to a common substrate, and a flexible beam 114 connecting the fan member 108 to the anchor 110. In addition, each bender 102 may include an EAP actuator 116 overlaying and mechanically coupled to the beam 114 for deflecting the bender 102. The actuator 116 may cover a portion (e.g., 50%) of the top surface of the flexible beam 114 or, in some embodiments, the entire top surface of the beam 114. In one embodiment, the beam 114 itself is an EAP actuator 116. In general, the size of the fan member 108 may range from 100 μm to a few mm (e.g., 1 to 10 mm), and the thickness of the fan member 108 may vary from a few μm (e.g., less than 10 μm) up to 1 mm.

The mechanical relationship between the benders 102 and the surface of the body to be cooled determines how cooling occurs, including the convection path. FIGS. 1E and 1F show opposed plan views of a two-dimensional array of benders 102; a thermal conductive frame or retention member 113 is affixed to one side of the array as shown in FIG. 1F. FIGS. 1G and 1H show alternative configurations in which, respectively, the benders are suspended above the body to be cooled or rise from the body to be cooled (or, more typically, from a frame thereon).

FIGS. 1G and 1H are sectional views of alternative cooling configurations. In FIG. 1G, the bender array 102 is suspended from the frame 113 (which is not seen in FIG. 1G). Hence, for the suspended embodiment shown in FIG. 1G, FIG. 1F is a top (plan) view of the frame 113 and the bender array therebeneath. In this embodiment, the benders 102 are raised above the substrate 112 by thermally conductive posts or supports 103 that are themselves in contact with the substrate. A forced convection regime is created in the narrow air gap between the benders 102 and the substrate 112, removing heat from the surface of the substrate 112. In order to achieve convective cooling, the kinetic energy of the aggregate flow produced by the benders 102 needs to overcome friction between the moving air and the surface of the substrate 112 in order to produce sufficient average velocity inside the gap.

In the alternative approach shown in FIG. 1H, the benders 102 are in thermal contact with the substrate 112, and hence more directly receive heat to be dissipated by convection. In addition to convective heat removal, the benders 102 act, collectively, as a heat sink. Of course, the operation of the benders 102 produces more efficient heat shedding than a stationary heat sink that depends solely on ambient air flow for convective cooling. In FIG. 1H, the benders 102 are shown as affixed to, or are fabricated so as to be integral with (i.e., “growing” out of) cooled substrate 112. More typically, however, they are affixed to the frame 113, which is itself mounted on the substrate 112—i.e., held against the substrate 112 by, for example, a thermal interface material, a thermally conductive epoxy, etc. Once again, the frame 113 does not appear FIG. 1H, but in this case FIG. 1E is a top view of the assembly (with the frame 113 hidden).

Thus, in this configuration, heat flows more directly from the substrate 112 to the benders 102 by conduction. To establish steady-state heat conduction and consequent cooling, self-cooling due to movement of the benders 102 plus the heat-sinking effects of the ambient air flow cool the benders 102 to an intermediate temperature between the substrate 112 and the cooler surrounding ambient. In particular, the benders 102 are cooled by flow around a stagnation region. The moving solid wall of each bender 102 pushes the stagnant air therebeneath and becomes heated. In this configuration, rather than having to overcome the frictional forces that promote stagnation, the benders 102 actually exploit the stagnation region to promote forced convective cooling. The convective heat-transfer coefficient in stagnation region flow is proportional to the square root of the bender's velocity.

The configuration shown in FIG. 1H benefits from the high heat conduction afforded by widespread contact with the substrate 112, and because the forced convection is not confined to a gap, it need not overcome friction and suffers less damping as a result. Nonetheless, neither design is necessarily superior and relative performance will depend on the specifics of the application.

In some embodiments, as illustrated in FIGS. 1E and 1F, the retention member 113 is in the form of a lattice conforming to the pattern of the benders 102, which are themselves formed in an array. In other embodiments, the retention member 113 may be solid slab, in which case it is desirably thin (e.g., 300 μm or thinner) and highly conductive thermally; for example, the retention member 113 may be silicon, with the benders 102 and supports 102a fabricated in accordance with a MEMS process as described below. The retention member 113 is itself cooled by free convection, which is usually negligible compared to stagnation-region convective cooling.

Referring again to FIGS. 1A and 1B, in various embodiments, the cooling system 100 includes a controller 118 and a control circuit 120 serving to control the power applied by the power supply 104 to the EAP actuator 116. When stimulated by an electric field, the EAP actuator 116 may exhibit a change in size and/or shape. For example, the electric field may cause the EAP actuator 116 to contract, in turn causing the normally flat beam 114 to deflect, and thereby causing the fan member 108 to move. The controller 118 may temporally vary the applied power with an operating frequency, f₁; as a result, the fan members 108 may vibrate at a resonance frequency, f₂, corresponding to the operating frequency (e.g., f₂=f₁, f₂=2f₁, etc.). This consequently produces an air flow 122 near the heat-generating component 106 to dissipate heat. As depicted, the generated flow rate at position 124 typically increases with the distance D from the heat-generating component 106 due to viscous effects at the surface. Typically, the applied voltages may range from 1 V to 8000 V and the operating frequencies may range from 1 Hz to 10 KHz. In addition, the cooling system 100 may include one or more sensors 126 to provide feedback to the controller 118. For example, the sensor 126 may be a flow sensor that detects a flow parameter (e.g., a flow rate and/or a flow direction) produced by the benders 102. If the detected flow parameter reach a predetermined value, the controller 118 may maintain the amplitudes, frequencies, and/or phases applied to the benders 102. If, however, the detected flow parameter does not reach or if it exceeds the predetermined value, the controller 118 may adjust the applied amplitudes, frequencies, and/or phases until the detected flow parameter satisfies the predetermined value. In some embodiments, the sensor 126 is a temperature sensor. The controller 118 adjusts the power applied to the benders 102 by comparing the detected temperature to a desired temperature to ensure a cooling effect is satisfied.

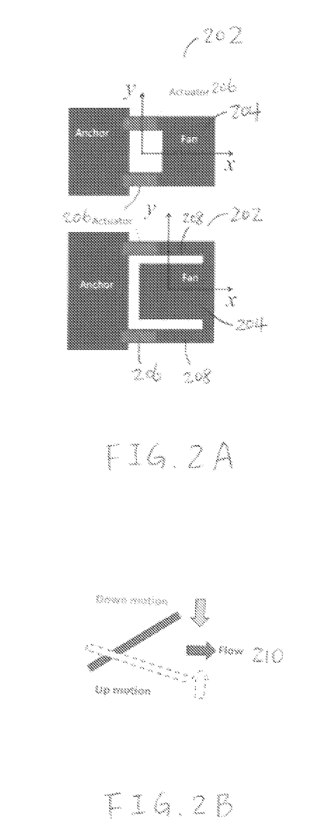

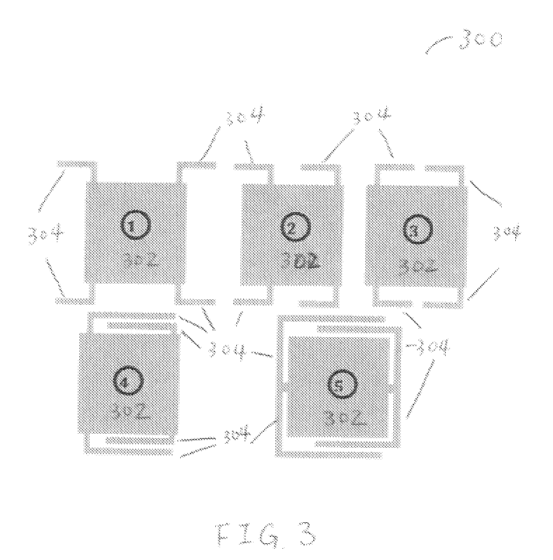

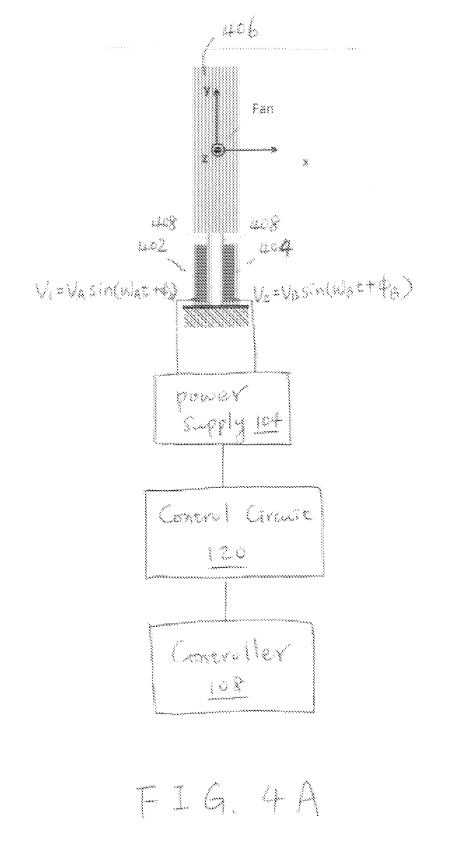

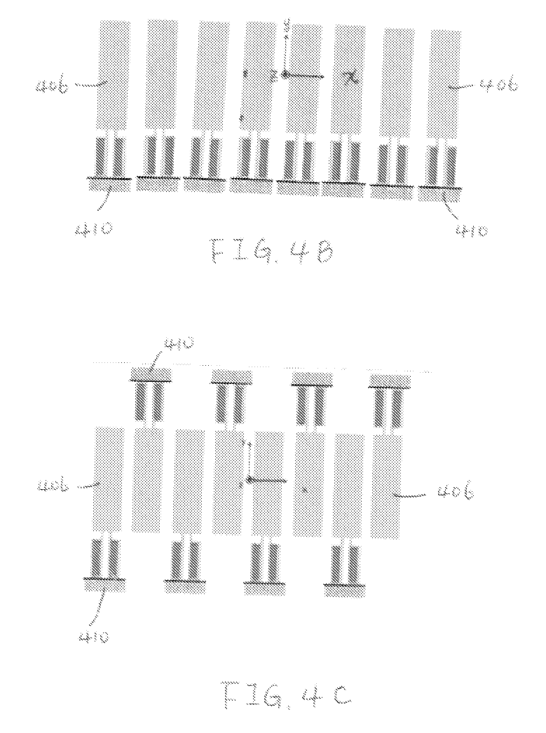

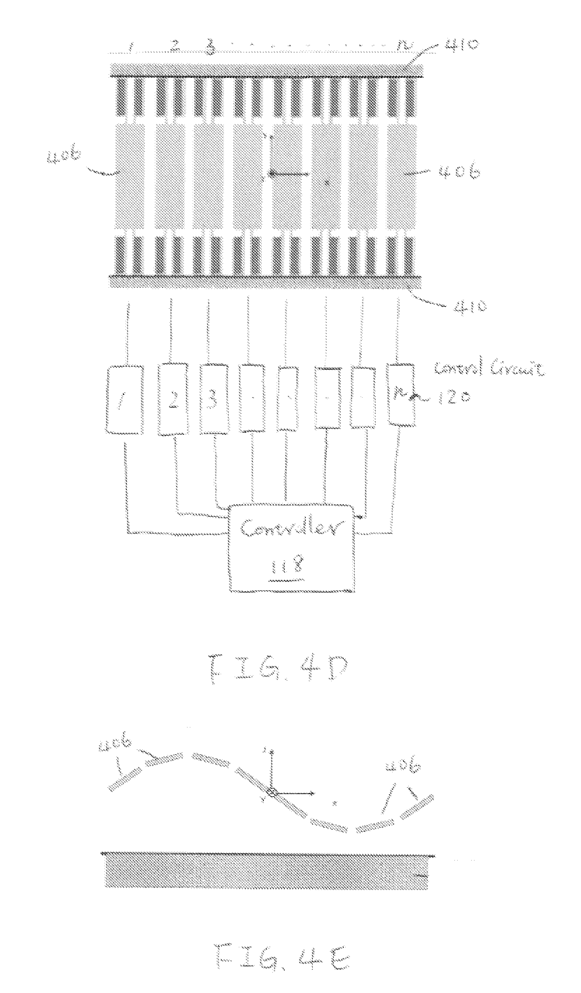

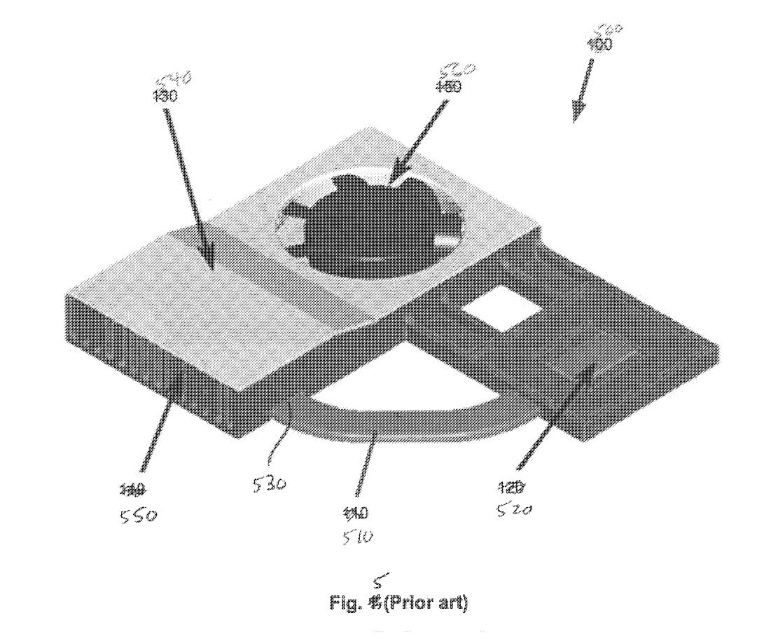

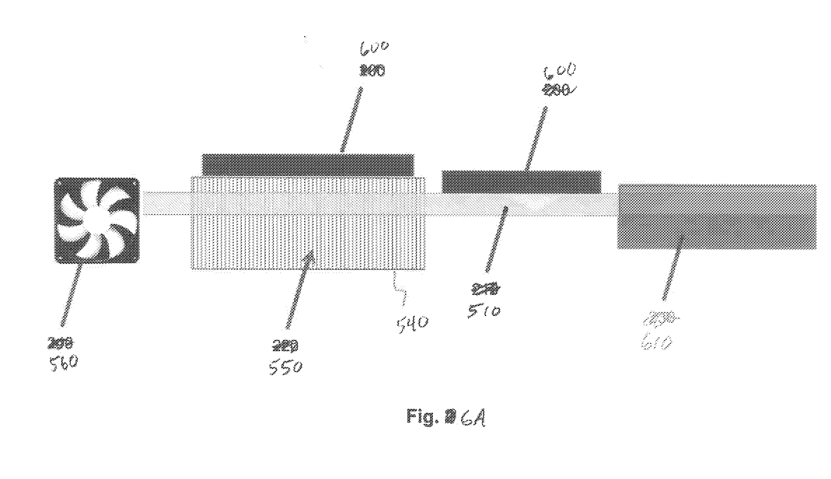

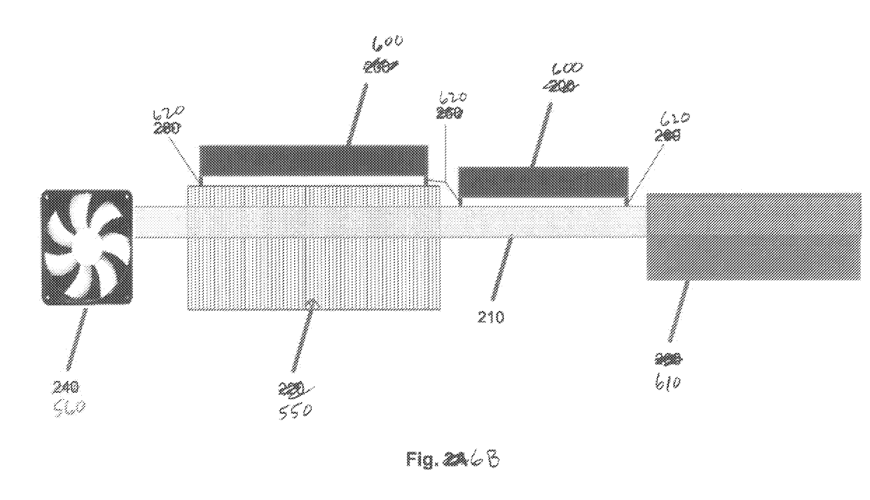

The benders 102 illustrated above represent exemplary embodiments only; they may include various configurations that are suitable for producing an air flow in an electronic device for heat dissipation and therefore are within the scope of the present invention. For example, referring to FIG. 2A, the bender 202 may include a fan member 204 and a pair of EAP actuators 206. When applying power to the pair of EAP actuators 206, they may change in size and/or shape and consequently cause the inclination thereof (and/or of the flexible beams 208 underlying of the actuators 206) to change through a range of motion during each actuation cycle (as depicted in FIG. 2B). The movement of the EAP actuators 206 and/or flexible beams 208 results in vibration of the fan member 204 and thereby produces an air flow 210.

FIG. 3 depicts various alternative bender configurations 300 in accordance with an embodiment of the present invention, where each fan member 302 has four actuators 304 (and/or four flexible beams) for moving the bender. As illustrated, the actuators 304 can be arranged in various configurations around the fan member 302.

Referring to FIG. 4A, in one embodiment, the power applied to each of the EAP actuators 402, 404 is separately controllable, i.e., one of the EAP actuators 402, 404 may be activated at an amplitude, a phase, and/or a frequency that is independent of the amplitude, phase, and/or frequency applied to the other EAP actuators 402, 404. For n EAP actuators, the controller 118 may contain n control circuits each comprising a phase-delay circuit and driving one of the EAP actuators with the respective phase. The controller 118 may split a control signal, typically in the range from 1 Hz to 10 KHz, into n channels for the n control circuits 120 for separately controlling each of the EAP actuators. For example, the controller 118 may be configured to activate the individual EAP actuators 402, 404 of the array at the same frequency (i.e., ω_{A}=ω_{B}), but at different phases (i.e., φ_{A} and φ_{B}, respectively) and different amplitudes (i.e., V_{A} and V_{B}, respectively). In another example, the controller 118 may activate the EAP actuators 402, 404 at the same frequency (i.e., ω_{A}=ω_{B}) and same amplitude (i.e., V_{A}=V_{B}), but at different phases (i.e., φ_{A} and φ_{B}, respectively). By adjusting the amplitudes, frequencies and/or phases applied to each actuator 402, 404, the fan member 406 may move, including deflecting, twisting, rotating, and/or vibrating, to create a desired flow parameter (e.g., a flow rate or a flow direction).

When simultaneously applying in-phase power (i.e., φ_{A}=φ_{B}) at the same frequency to the pair of EAP actuators 402, 404, the motion of the fan member 406 has two degrees of freedom, including deflection in the vertical (z) direction and rotation (or tilting) around the x axis. If, however, the EAP actuators 402, 404 are operated with a phase shift therebetween (e.g., φ_{A} and φ_{B} have a phase difference of 180°), the motion of the fan member 406 may include an extra degree of freedom—i.e., rotation around the y axis. In one embodiment, the flexible beams 408 includes a highly compliant material (e.g., an AEP) that allows the fan member 406 to rotate through a large angle (e.g., 45°) around the y axis to enhance the produced air flow.

The benders may be arranged in various configurations. For example, referring to FIGS. 4B and 4C, each fan member 406 may be affixed to a substrate 410 on one side only. The fan members 406 may be oriented parallel to one another, where the same side of each fan member is clamped to the substrate 410 (FIG. 4B); or the fan members 406 may be anti-parallel to one another, where the opposite sides of two neighboring fan members 406 are clamped to the substrate 410 (FIG. 4C). In the embodiment shown in FIG. 4D, two opposite sides of the fan members 406 are both attached to the common substrate 410. One of ordinary skill in the art will understand that the illustrated bender array may have more configurations, i.e., the benders may be arranged in any manner that is suitable for producing a desired flow parameter(s) (e.g., a desired flow rate and/or a flow direction).

In various embodiments, the power applied to the benders is separately controllable, i.e., each bender may be activated at amplitudes, phases, and/or frequencies that are independent of the amplitudes, phases, and/or frequencies applied to the other benders. For n benders, the controller 118 may split a control signal into n channels for n control circuits, each control circuit associated with a bender, for separately controlling each of the benders. For example, the controller 118 may be configured to actuate the benders of the array at the same frequency and amplitude, but at different phases. As a result, with reference to FIG. 4E, the fan members 406 of the benders may move in the z direction and rotate around the y axis to various degrees, depending on the phases applied thereto, and thereby form a “wave” travelling in the x direction. This design may create an efficient air flow for heat dissipation. Additionally, the “wavelength” of the travelling “wave” may be adjusted by changing, for example, the width of the fan members and/or the number of fans per unit length, to produce a desired flow parameter.

In one embodiment, the controller 118 groups the fan members 406 into multiple subsets, each corresponding to fan members separated by a distance corresponding to the wave period; each subset is sequentially activated to produce the illustrated wave-like behavior and thereby achieve a predetermined flow parameter. Alternatively, each subset of the fan members 406 may be activated randomly or in any desired manner to individually or collectively create an air flow at one or more locations near the heat-generating component. In sum, the present invention provides an approach enabling the controller 118 to repeatedly activate individual fan members 406 or subsets thereof in a synchronized or unsynchronized manner to generate synchronized or unsynchronized vibration. In other embodiments, the controller 118 actuates the benders via a single control circuit 120—i.e., the benders are simultaneously activated at the same amplitude with the same frequency and same phase; this obviates the need of multiple control circuits 120, thereby simplifying the circuitry design.

The controller 118 desirably provides computational functionality, which may be implemented in software, hardware, firmware, hardwiring, or any combination thereof, to compute the required frequencies and amplitudes for a desired flow parameter. In general, the controller 118 may include a frequency generator, phase delay circuitry, and/or a computer (e.g., a general-purpose computer) performing the computations and communicating the frequencies, phases and amplitudes for the individual EAP actuators 116 to the power supply 104. For embodiments in which the functions are provided as one or more software programs, the programs may be written in any of a number of high level languages such as FORTRAN, PASCAL, JAVA, C, C++, C#, BASIC, various scripting languages, and/or HTML. Additionally, the software can be implemented in an assembly language directed to the microprocessor resident on a target computer; for example, the software may be implemented in Intel 80×86 assembly language if it is configured to run on an IBM PC or PC clone. The software may be embodied on an article of manufacture including, but not limited to, a floppy disk, a jump drive, a hard disk, an optical disk, a magnetic tape, a PROM, an EPROM, EEPROM, field-programmable gate array, or CD-ROM. Embodiments using hardware circuitry may be implemented using, for example, one or more FPGA, CPLD or ASIC processors. Such systems are readily available or can be implemented without undue experimentation.

The configurations of the benders provided herein are for illustration only, and the present invention is not limited to such configurations. One of ordinary skill in the art will understand that any variations are possible and are thus within the scope of the present invention. For example, the number of benders per electronic device, the configuration of the bender array, and/or the size, shape or orientation of the benders may be modified in any suitable manner for generating an air flow to dissipate heat generated in the electronic device. In addition, the controller 118 may actuate the EAP actuators 116 associated with the fan members to create movements of the fans simultaneously, sequentially, or in any desired manner to collectively produce a desired flow parameter (e.g., a flow rate and/or a flow direction).

Additionally, the benders may not be necessarily supplied by a power source—i.e., they may be static. In some embodiments, by adjusting the shape, size, and/or orientation of each bender, the density of the bender array (i.e., the number of benders per unit area), and/or the distance between the benders to the heat-generating component, the presence of the bender array itself is sufficient to produce a cooling effect. Without being bound to any particular theory or mechanism, this may be caused by, for example, efficient heat dissipation by the high thermal conductive surface area and varied geometry of the benders and/or bender motion resulting from a thermal gradient across the benders created by the heat-generating component 106. The thermal gradient may be self-reinforcing as air is forced through the narrow channels beneath the benders.

The benders 102 may be manufactured utilizing techniques including, but not limited to, MEMS and/or other suitable manufacturing techniques. The use of MEMS technology advantageously allows the cooling system to be manufactured in a sufficiently compact size such to be accommodated in devices having severe space constraints. In one embodiment, the fan member, flexible beam and anchor are fabricated from a single material (using a MEMS fabrication process), and the actuator material is applied thereto by deposition, screening, or other suitable application process. If the substrate is silicon (Si), selective masking and etching steps may be employed to fabricate the fan and beam members directly from the substrate surface. The actuators may include or consist essentially of any materials that exhibit a change in size or shape when stimulated by an electric field, and provide advantages over some traditional electroactive materials such as electro-ceramics for MEMS device applications due to their high strain, light weight, flexibility and low cost. The actuators may be divided into two classes: electrochemical (also known as “wet” or “ionic”) and field-activated (also known as “dry” or “electronic”). Electrochemical polymers use electrically driven mass transport of ions to effect a change in shape (or vice versa). Field-activated polymers use an electric field to effect a shape change by acting on charges within the polymer (or vice versa).

One of the most widely exploited polymers exhibiting ferroelectric behavior is poly(vinylidene fluoride), a family of polymers commonly known as PVDF, and its copolymers and terpolymers. These polymers are partly crystalline and have an inactive amorphous phase. Their Young's moduli are between 0.3 and 5 GPa. This relatively high elastic modulus offers a correspondingly high mechanical energy density, so that strains of nearly 7% can be induced. Recently, P(VDF-TrFE-CFE) (a terpolymer) has been shown to exhibit relaxor ferroelectric behavior with large electrostrictive strains and high energy densities. All of these materials may be used advantageously in accordance herewith.

Exemplary techniques for manufacturing the benders 102 and frame 113 are described, for example, in the '107 and '009 applications.

### B. Integration

For illustrative purposes, FIG. 5 illustrates a conventional fan-based cooling solution 500 for microprocessors and chip-based devices. The system 500 includes a heat pipe 510 having a collection end 520 and a discharge end 530. The collection end overlies the chip to be cooled via a thermal interface, and the discharge end leads to an exit manifold 540 that includes a series of heat-exchange fins or vanes 550. The heat pipe 510 is typically a solid metallic (e.g., copper) pipe. Through a process of vaporization and recondensation, heat travels through the heat pipe 510 to the heat-exchange fins 550. Heat transport is assisted by a rotary fan 560 that circulates air through the manifold 540.

A low-profile convective cooling unit such as any of those illustrated in FIGS. 1-4E may be combined with the conventional system 500 to enhance the efficiency thereof. One exemplary implementation, shown in FIG. 6A, utilizes one or more generally planar cooling units 600, which may be realized most simply as an array of benders 102 (see FIG. 1A) distributed over the surface of the manifold 540 and/or the exposed portion of the heat pipe 510. Alternatively, manufacturing considerations may favor fabrication of the benders 102 on a retention member 113 (see FIG. 1F), which is itself secured via a thermal interface (e.g., thermally conductive epoxy) to the manifold 540 and/or heat pipe 510. As the fan 560 draws air through the heat pipe 510, the device 610 is cooled, and heat is dissipated via the fins 550 and the cooling unit(s) 600. In some embodiments, the efficiency of the cooling units 600 obviates the need for the fan 560. In these embodiments, the device 610 to be cooled need not be modified or directly attached to the cooling unit(s) 600. In still other embodiments, the cooling unit 600 cools the heat pipe 510, and may obviate the need for vanes 550 and the manifold 540.

As explained above, a retention member may take the form of a solid slab, in which case it is desirably thin (e.g., 300 μm or thinner) and highly conductive thermally; or may be in the form of a grating with gaps between adjacent rows or columns of benders. To achieve the operational mode described in connection with FIG. 1E or for other performance reasons, the cooling systems 600 may be spaced apart from the underlying structures by a series of thermally conductive spacers 620 as shown in FIG. 6B. This permits, for example, the benders to be suspended from the retention member over the structure to be cooled. Spacers may similarly be used with any of the embodiments described below. Suitable materials for the spacers include metal, polymer, glass, quartz, and silicon.

In some embodiments, the cooling device 600 is associated directly with the fins 550 rather than the manifold 540. With reference to FIG. 6C, the cooling device 600 may include a retention member 640 in the form of a slab that is attached, via a thermal interface (e.g., thermally conductive epoxy) to the coplanar edges of multiple fins 550. For example, the retention member 640 may replace a portion of the manifold housing. In another approach, the cooling devices 600 may alternate with or, as shown in FIG. 6D, be joined to the fins 540. In some embodiments, the retention member of a cooling device is adhered to one or both sides of a fin 540 using, for example, thermally conductive epoxy, but it is also possible to fabricate the benders 102 as integral parts of fins 540—that is, the fins 540 themselves serve as the retention member and the benders are attached thereto or fabricated integrally therewith as described above with respect to FIG. 1F.

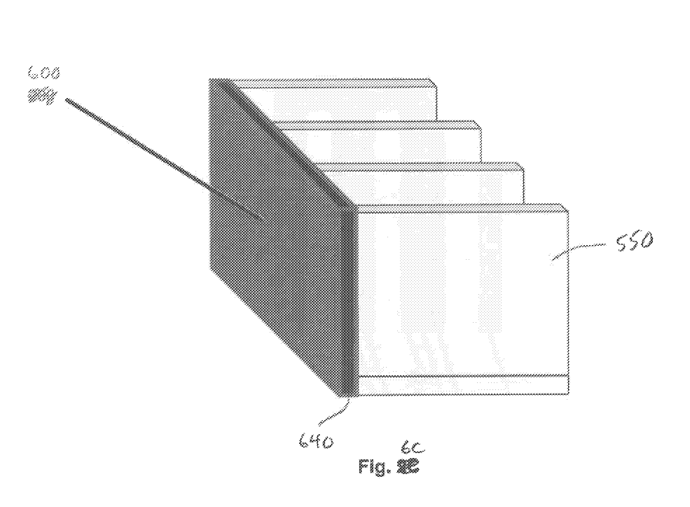

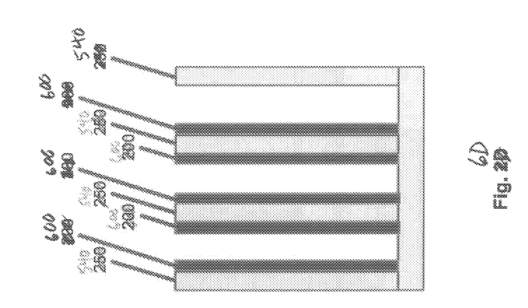

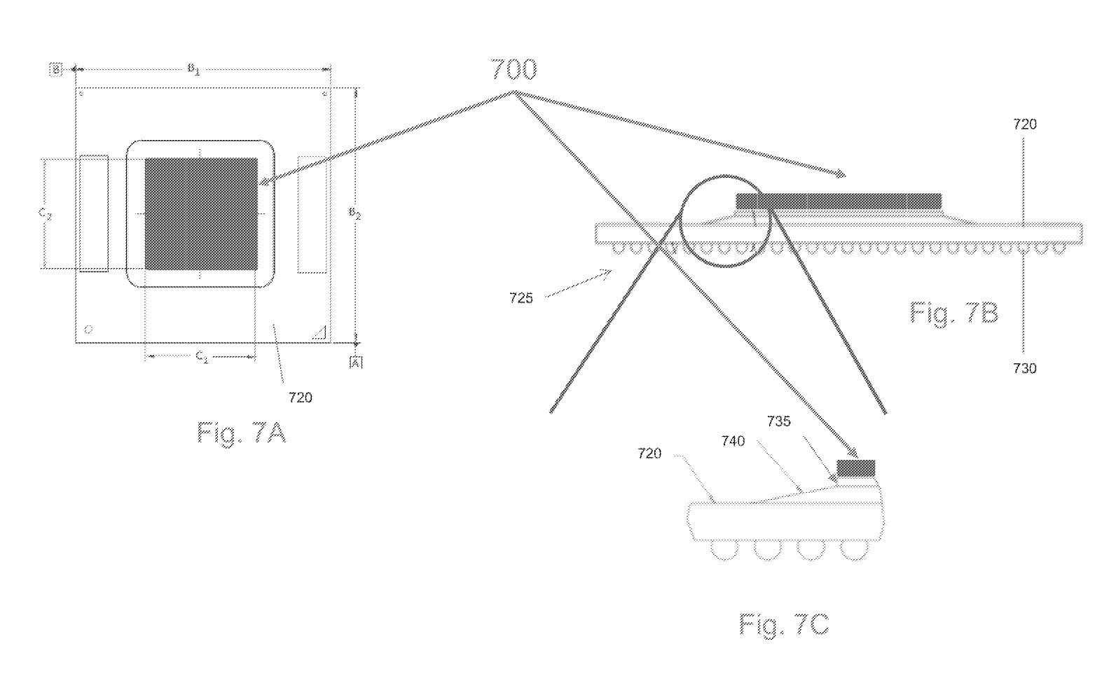

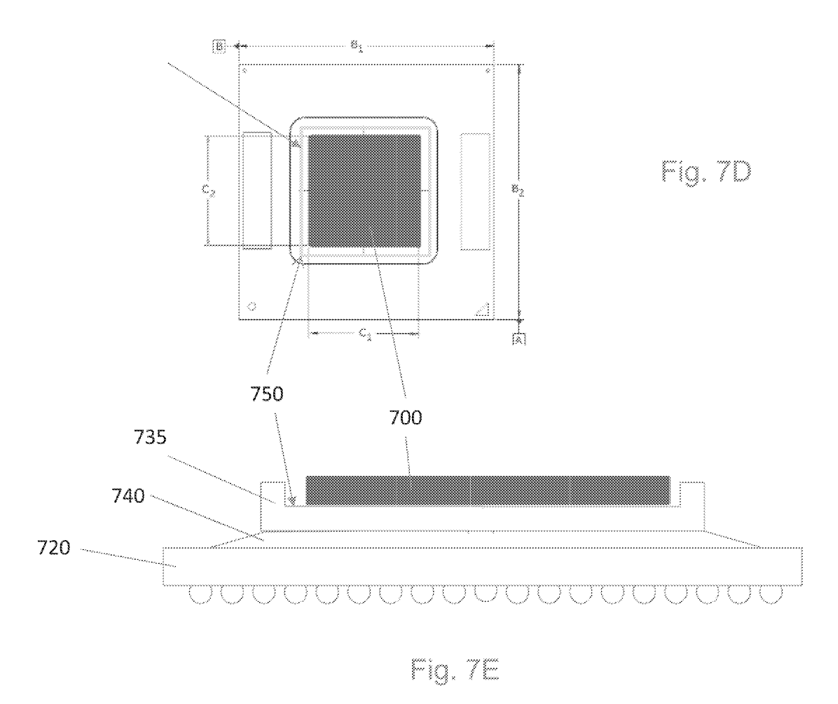

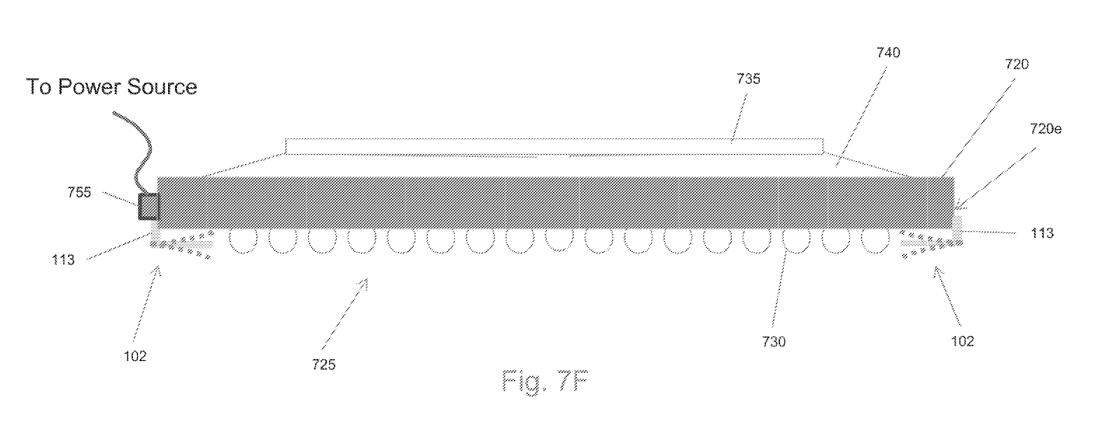

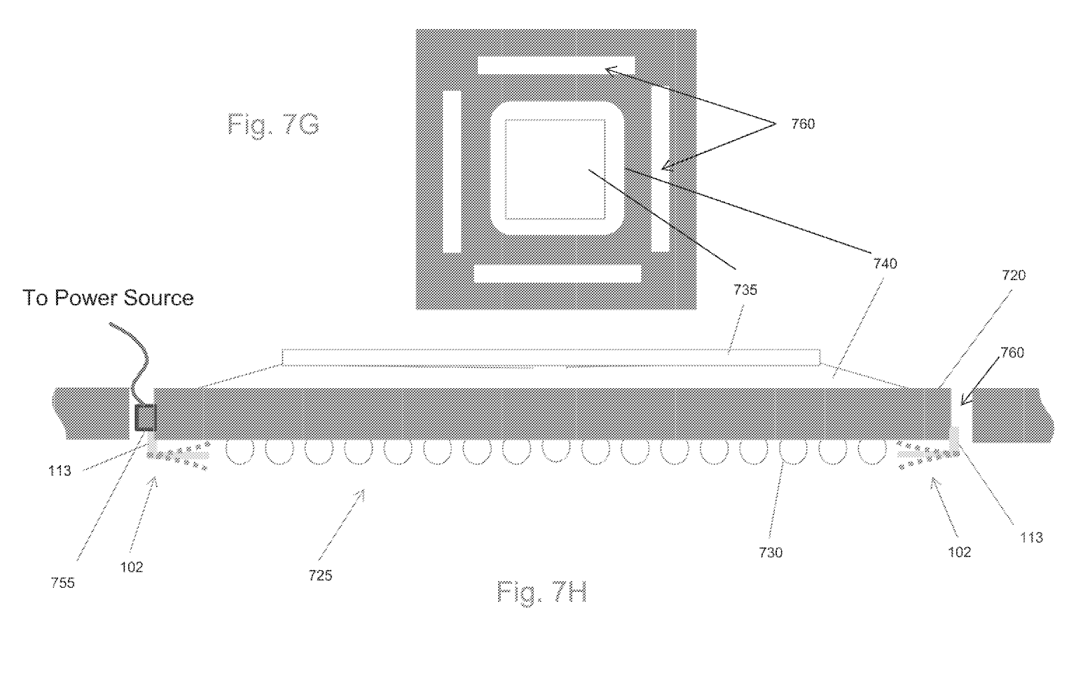

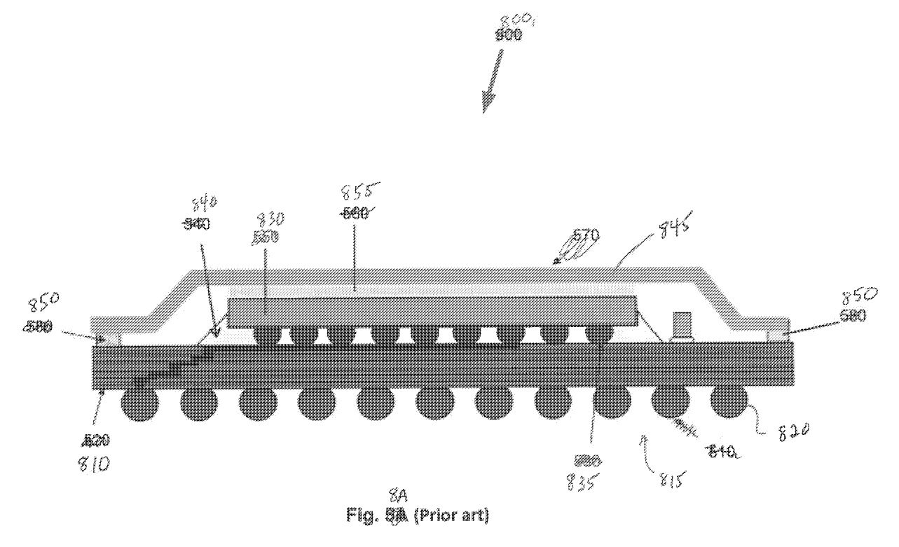

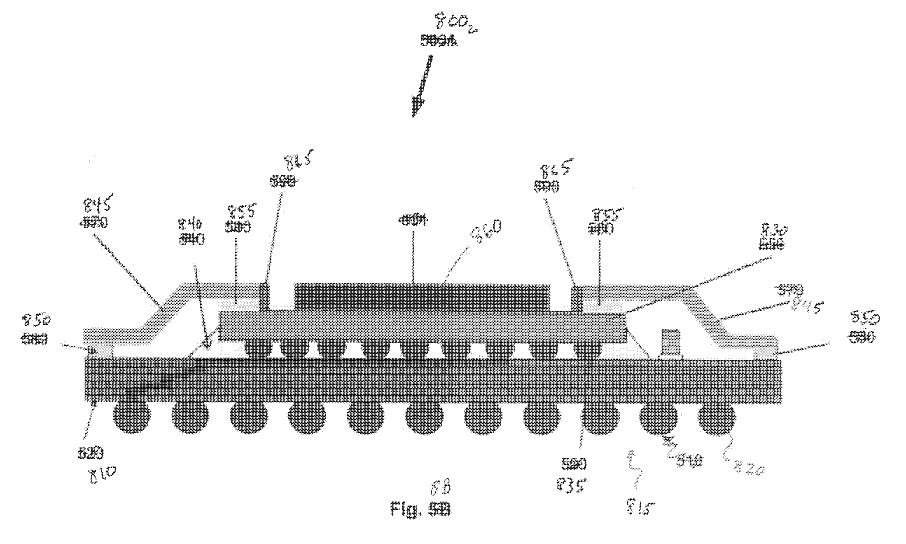

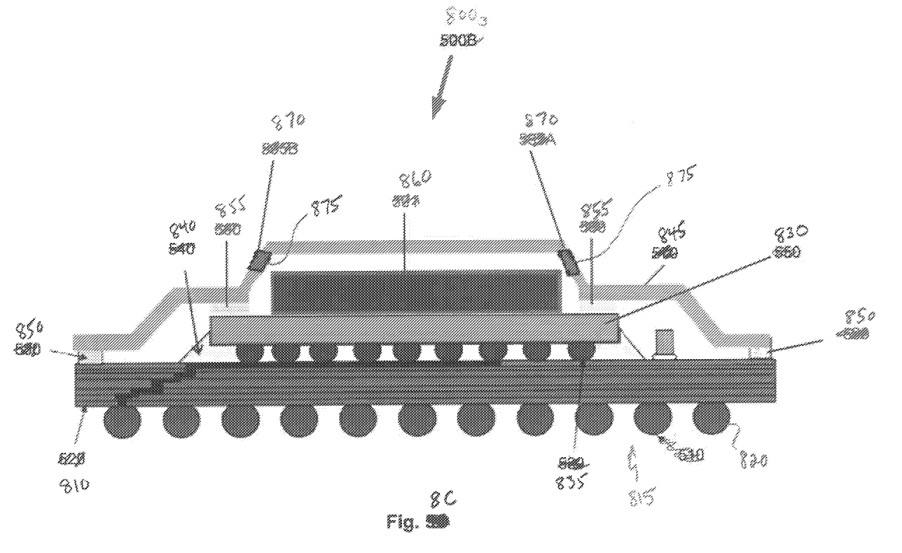

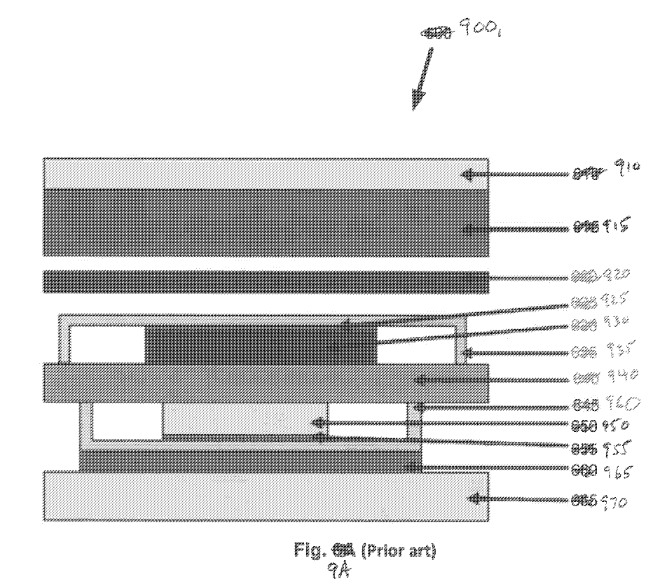

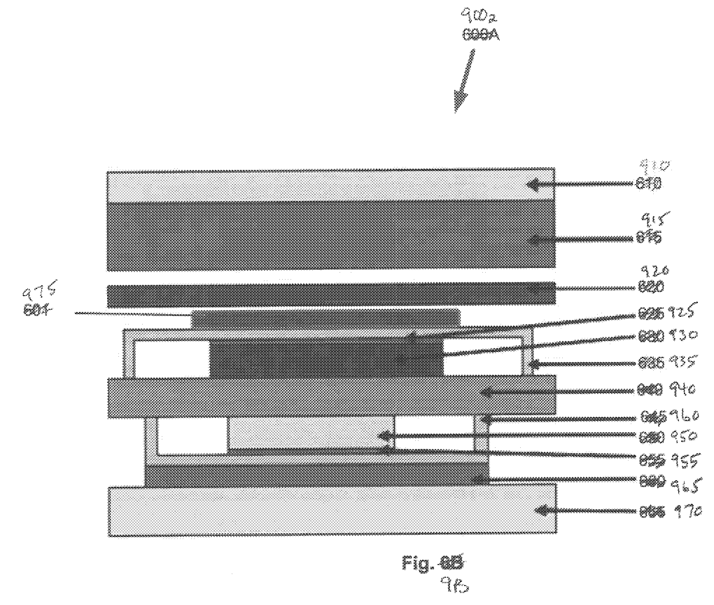

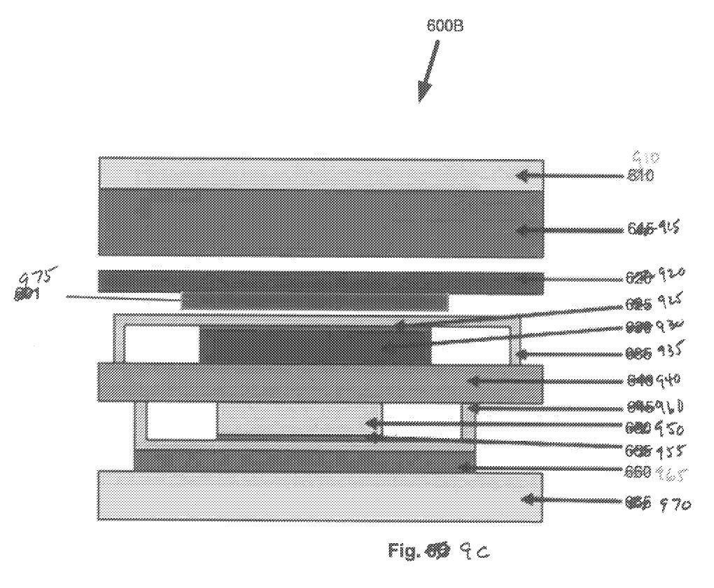

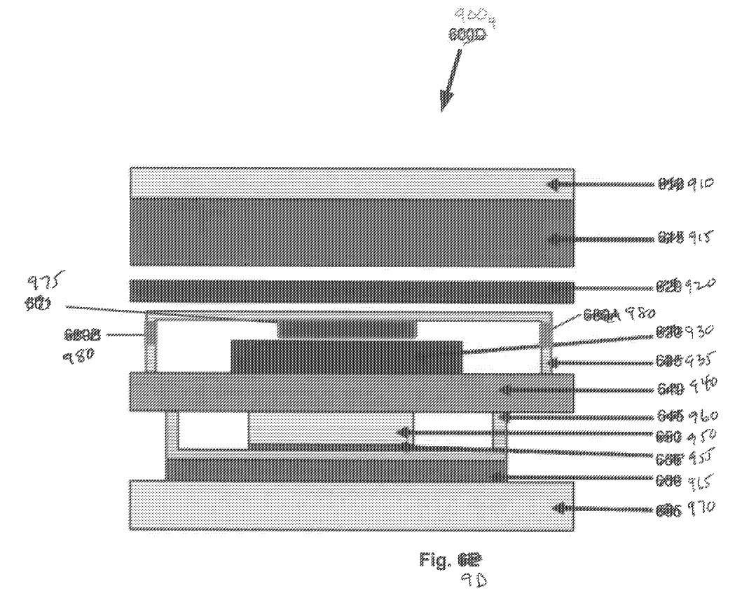

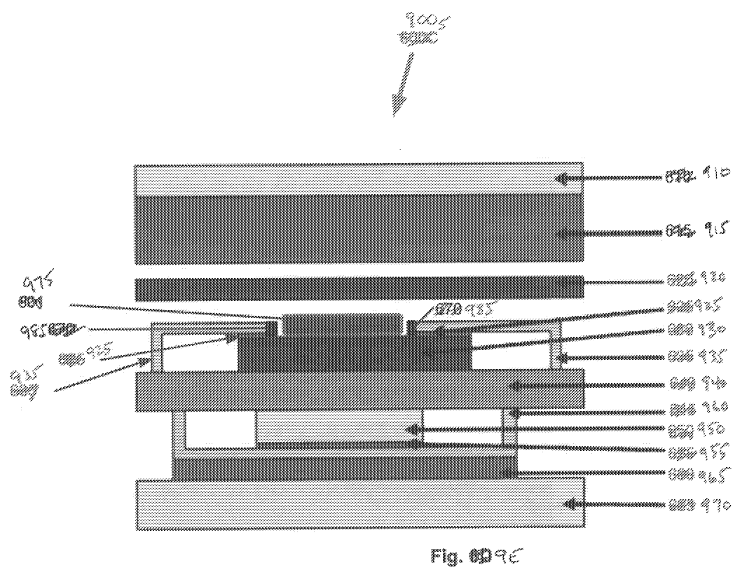

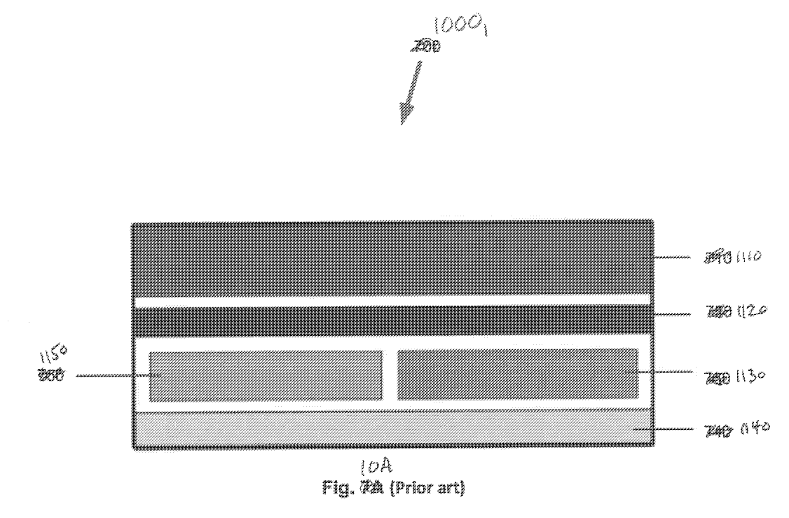

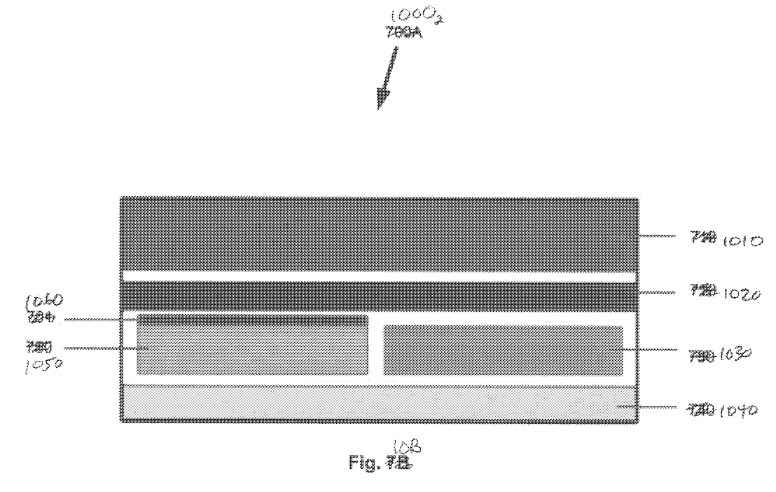

In other embodiments, and with reference to FIGS. 7A-7C, a low-profile convective cooling unit 700 is associated with the component-level device 710 (e.g., an integrated circuit) itself rather than with surrounding cooling structures. These external cooling structures may, in fact, be omitted if cooling by the unit 700 is sufficient. The device 710 includes a package substrate 720 having, on one side, an array 725 of contacts 730, e.g., a ball grid array. As best seen in FIG. 7C, the actual device die 735 is adhered to the package substrate 720 by means of an “underfill,” which is typically an electrically insulating adhesive. The underfill material 740 also acts as an intermediate between the difference in thermal-expansion coefficient of the die 735 and the package substrate 720. The cooling system 700 cools the surface of the die 735. In some embodiments, the cooling system 700 comprises an array of benders 102 (see FIG. 1A) on a retention member that is adhered to the surface of the die 735 by means of a thermally conductive adhesive. In other embodiments, however, the cooling system 700 is part of the die 735 and may be co-fabricated therewith as a separate composite layer. In some embodiments the die 735 is electrically connected to the cooling system 700, providing power and control signals thereto by means of wires and vias. In other embodiments, the cooling system 700 is electrically connected to the contacts 730 and receives power and control signals therefrom. In still other embodiments, the cooling system 700 is connected both to the die 735 and to the contacts 730, e.g., receiving control signals from the die 735 and power via the contacts 730. In other embodiment the cooling system 700 is part of the component packaging, for example by using the Package on Package (PoP) method.

To reduce or eliminate the extra height (i.e., device thickness) imposed by the cooling unit 700, it may be disposed within an in-die cavity 750 within the die 735 as illustrated in FIGS. 7D and 7E. This cavity 750 may be fabricated, for example, during “back-end” processing of the die 735—e.g., following conventional back-thinning and lithography, the cavity 750 may be formed by reactive etching, e.g., deep reactive-ion etching (DRIE).

Alternatively or in addition, the package substrate may be cooled by disposing benders along one or more peripheral edges. With reference to FIG. 7F, a plurality of benders 102 are affixed to a frame 113, which itself is in contact with one or more peripheral edges 720e of the substrate 720. For example, the frame 113 may be disposed along two, three or all four contiguous edges of the package substrate 720 with the benders disposed along the bottom of the frame 113 so as to create convection around, and thereby cool, the ball grid array 725 in the gap beneath the substrate 720. In some embodiments, benders 102 are also disposed along the top of the frame 113 to cool the top surface of the substrate 720. If driver circuitry is not included within the die 735, it may be provided as a separate component 755 that is connected to a suitable power source.

In a variation, shown in FIGS. 7G and 7H, the benders 102 may be disposed within gaps 760 created through the package substrate 720 or a circuit board rather than along a peripheral edge. The openings 760 may be created by laser, knife, punch or any other suitable technique.

In some cases the die 735 is not exposed, but is instead part of a larger packaging structure. With reference to FIG. 8A, a conventional ASIC 800₁ includes a device substrate 810 (which is typically polymeric and multilayered) having, on one side, an array 815 of external contacts 820, e.g., a ball grid array. The die 830 is in a “flip chip” configuration with a series of internal c4 “bump” contacts 835 connecting the exposed face of the die 830 to the external ball grid array 815 via the device substrate 810. An underfill material 840 anchors the die 830 to the device substrate 810. To accommodate high-power (e.g., 50-200 W) operation, a metal “lid” 845 overlies the die 830 and is anchored to the package substrate by one or more rim seals 850. A thermal interface material 855 transfers heat from the die 830 to the lid 845, which dissipates the heat by radiation and convection. In other words, heat dissipation from the device 800₁ is passive.

As shown in FIG. 8B, a modified device 800₂ incorporates a low-profile cooling system 860 as described herein. As discussed above, the cooling system 860 may be adhered to the surface of the die 830 by means of a thermally conductive adhesive or may instead be part of the die 830 and, if desired, co-fabricated therewith as a separate composite layer. In the device 800₂, the lid 845 is provided with an opening bounded by a peripheral seal 865 that isolates the remainder of the die 830 from the outside. Although a space is shown between the cooling system 860 and the seal 865, in practice there may be no space between them. In the illustrated configuration, the cooling system 860 overlies most of the area of the die 830, and the small remaining portion is cooled in the conventional manner via the lid 845.

In some circumstances (e.g., in environments where the device may suffer physical contact), it may be preferable to retain the lid 845, in which case the lid may be provided with a series of “porthole” openings 870 around a peripheral surface thereof to permit entry and exit of air as shown in FIG. 8C. A strip of filter material may surround the interior of the peripheral surface, or individual plugs 875 of filter material may span each of the openings 870, so as to limit the entry of contaminants through the openings. For example, the filter(s) may be selective to maintain the integrity of the interior environment (e.g., preventing egress of nitrogen) of the device 800₃. Alternatively, the openings 870 may be numerous but individually small, thereby acting collectively as a particulate filter.

A representative product-level device 900₁, which may be a smart phone or tablet, is illustrated in FIG. 9A. The device includes a front plate 910 that represents the user-facing surface of the device 900; a display 915; a middle plate 920, which provides structural stiffening to the device 900; an inner pad 925; a circuit component 930 (which may bear the CPU and/or memory of the device 900₁, for example); a shield 935 protecting the component 930; a printed circuit board (PCT) 940 on which the primary electronic components of the device 900 are mounted; a second component and inner pad 950, 955, also surrounded by a shield 960; an outer pad 965; and a back plate 970. The functions of these components are conventional and well-understood by those skilled in the art.

As illustrated in FIGS. 9B and 9C, a low-profile cooling unit 975 can be introduced between the shield 935 and the middle plate 920, and attached either to the shield 935 (FIG. 9B) or to the middle plate 920 (FIG. 9C). In the former case, the cooling unit 975 may provide sufficient structural support to permit omission of the middle plate 920. Alternatively, as shown in FIG. 9D, the cooling unit 975 may be disposed on the upper interior surface of the shield 935, which may obviate the need for a portion or the entirety of the inner pad 925 (see FIG. 9A); as illustrated, an air gap may separate the cooling unit 975 from the component 930. The shield 935 may be provided with a series of porthole openings 980 around the supporting wall thereof to permit entry and exit of air. Once again a strip of filter material may be provided around the interior surface of the supporting wall, or individual plugs of filter material may span each of the openings 980, so as to limit the entry of contaminants through the openings and/or may be selective to maintain the integrity of the interior environment.

In still another embodiment, illustrated in FIG. 9E, the top surface of the shield 935 is opened to expose the cooling unit 975. The cooling unit 975 may be adhered to the surface of the inner pad 925 by means of a thermally conductive adhesive. In the device 900₅, the opening in the shield 935 is bounded by a peripheral seal 985 that isolates the remainder of the component 930. Although a space is shown between the cooling unit 975 and the seal 985, in practice there may be no space between them. In the illustrated configuration, the cooling unit 975 overlies most of the area of the component 930. The inner pad 925 may be thermally conductive to transfer heat from the component 930 to the cooling unit 975 and the shield 935. In all embodiments 900₂-900₅, the peripheral edge of the device 900 may be provided with one or more ventilation ports or with a series of “porthole” openings to assist convective cooling.

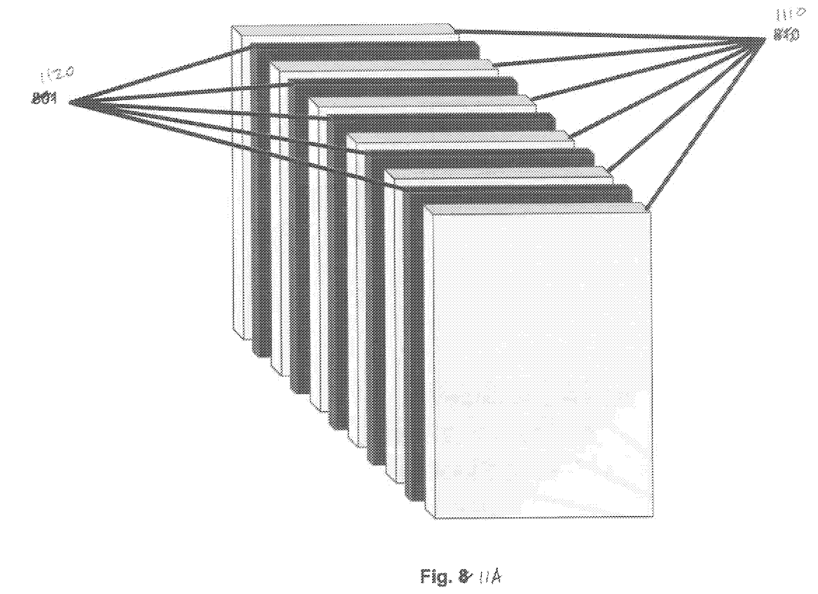

In still another embodiment, a low-profile cooling system may be associated with the battery (or batteries) powering a product-level device. With reference to FIG. 10A, a product-level device 1000₁ (such as a smart phone or tablet) includes a display 1010, middle plate 1020, a PCB 1030 on which the primary operative components of the device are mounted, a back plate 1040 and a battery 1050. As shown in FIG. 10B, the cooling system 1060 is attached on top of the battery 1050, either in flush contact or spaced apart by spacers as discussed above. The peripheral edge of the device 1000 may be provided with one or more ventilation ports or with a series of “porthole” openings (not shown) to assist convective cooling. Furthermore, depending on the heat profile of the device 1000₂, one or more additional cooling units 1060 may be included within the device as described, for example, in connection with FIGS. 9B-9E.

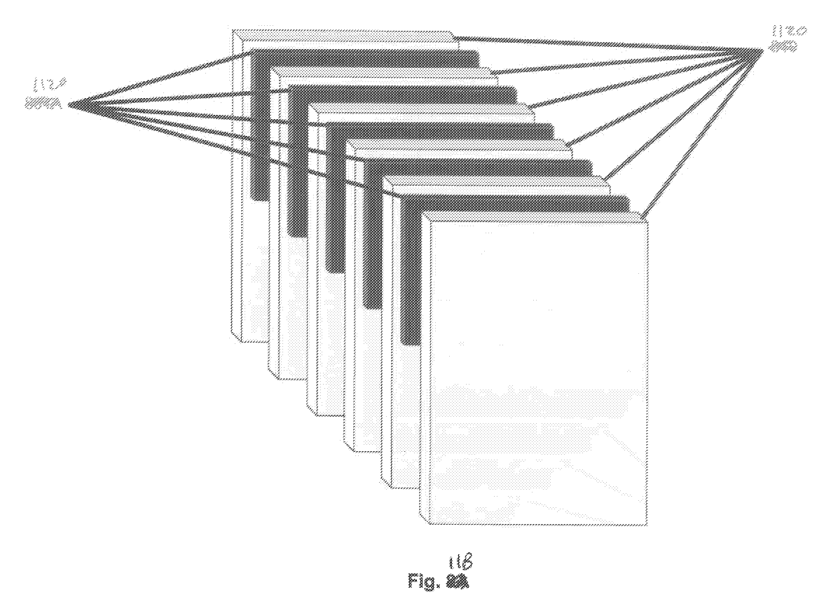

In cases where the battery consists of a plurality of adjacent (e.g., stacked) cells 1110, as shown in FIGS. 11A and 11B, a complementary series of cooling systems 1120 may be located therebetween. The cells 1110 and the cooling systems 1120 may be a really coextensive, as shown in FIG. 11A, or the cooling systems 1120 may cover only a portion of the area of the cells 1110. Space may be left (by means, e.g., of spacers) between the cells 1110 and the cooling systems 1120 to enhance convective flow.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. A cooling device comprising:
a plurality of benders each comprising (i) a fan member, (ii) a beam, and (iii) at least one electroactive actuator associated with the beam for transmitting force thereto, the electroactive actuators being responsive to a time-varying electrical signal whereby the fan members vibrate at a frequency corresponding to the signal and collectively produce an air flow;
wherein at least two fan member vibrate about different axes and wherein flows produced by the benders are substantially additive.

2. The device of claim 1, further comprising heat-collecting surface, a heat-exchange manifold comprising a plurality of vanes, and a heat pipe having a first end in thermal contact with the heat-collecting surface and a second end in contact with the heat-exchange manifold, wherein the benders are integral with or attached to the heat pipe.

3. The device of claim 1, further comprising heat-collecting surface, a heat-exchange manifold comprising a plurality of vanes, and a heat pipe having a first end in thermal contact with the heat-collecting surface and a second end in contact with the heat-exchange manifold, wherein the benders are integral with or attached to one side of a plurality of the vanes.

4. The device of claim 3, wherein benders are integral with or attached to both sides of a plurality of the vanes.

5. The device of claim 1, wherein the benders are arranged on a thermally conductive retention member.

6-10. (canceled)

11. The device of claim 1, wherein the electroactive actuator is mechanically coupled to the beam.

12. The device of claim 1, wherein the beam is made of an electroactive polymer.

13. A self-cooling integrated circuit comprising:
an integrated circuit die;
a device substrate having a first surface to which a first surface of the die is attached, the device substrate including a plurality of contacts on a second surface thereof opposed to the first surface, at least some of the contacts facilitating electrical connection to the die; and
the device according to claim 1, wherein said plurality of benders are distributed over a second surface of the die opposed to the first surface.

14. The integrated circuit of claim 13, wherein the benders are suspended by a retention member above the second surface of the die.

15. The integrated circuit of claim 13, wherein the benders rise from a retention member in contact with the second surface of the die.

16. The integrated circuit of claim 13, wherein the cooling unit is electrically connected to the die.

17. (canceled)

18. The integrated circuit of claim 13, wherein the cooling unit is electrically connected to the contacts.

19. (canceled)

20. The integrated circuit of claim 13, wherein the cooling unit is spaced from the die by a plurality of thermally conductive spacers.

21. The integrated circuit of claim 13, wherein die has a cavity and the cooling unit resides within the cavity.

22. The integrated circuit of claim 13, wherein the benders are arranged on a thermally conductive retention member.

23. The integrated circuit of claim 13, wherein the benders are arranged on and integral with the second surface of the die.

24. The integrated circuit of claim 13, wherein the benders all have a common orientation so that the flows produced by the benders are substantially additive.

25. The integrated circuit of claim 13, wherein at least some of the benders have different orientations.

26. The integrated circuit of claim 13, wherein the electroactive actuator is mechanically coupled to the beam.

27. The integrated circuit of claim 13, wherein the beam is made of an electroactive polymer.

28. The integrated circuit of claim 13, further comprising a metal lid overlying the die.

29-30. (canceled)

31. A method of manufacturing a self-cooling device, the method comprising:
fabricating an integrated circuit die;
fabricating, on the die, a plurality of benders, each comprising (i) a fan member, (ii) a beam, and (iii) at least one electroactive polymer associated with the beam for transmitting force thereto, in a manner that at least two fan member vibrate about different axes and oriented to generate substantially additive flows.

32. The method of claim 31, wherein fabricating the benders comprises providing electrical connections between the benders and the die.

33. The method of claim 31, wherein the plurality of benders are formed utilizing micro-electromechanical system (MEMS) technology.

34. The method of claim 31, wherein formation of the benders comprises the steps of:
forming a substrate over the die;
forming a first electrode layer on the substrate;
depositing an electroactive polymer on the first electrode layer;
forming a second electrode layer;
releasing a portion of the substrate from the first electrode layer;
releasing the electroactive polymer; and
separating the plurality of the benders.
